(19) United States
(12) Patent Application Publication
(10) Pub. No.: US 2022/0350738 A1
(43) Pub. Date: Nov. 3, 2022

(54) DYNAMICALLY STORING DATA TO DATA STORAGE DEVICES WITHIN PRE-DEFINED COOLING ZONES

(71) Applicant: Seagate Technology LLC, Fremont, CA (US)

(72) Inventors: Xiong Liu, Singapore (SG); Li Hong Zhang, Singapore (SG)

(73) Assignee: Seagate Technology LLC, Fremont, CA (US)

(21) Appl. No.: 17/242,643

(22) Filed: Apr. 28, 2021

(51) Int. Cl. G06F 12/0802; G06F 1/20; H05K 7/20

(52) U.S. Cl. CPC G06F 12/0802; G06F 1/206; H05K 7/20209; G06F 2212/152

(57) ABSTRACT

A method includes receiving a write command including data to be stored and a logical block address associated with the data. The method includes selecting, from a pre-defined plurality of cooling zones of a data storage chassis, a cooling zone in which to store the data. The method further includes writing the data to a data storage device in the cooling zone.

BACKGROUND

Data centers include vast amounts of data storage devices housed in numerous cabinets or racks. The data storage devices may be supported by significant infrastructure including networking equipment, power supplies and environmental controls, among other things. The data storage devices generate large amounts of heat, which may decrease the lifespan of the data storage devices. Cooling large number of data storage devices consumes enormous amounts of power and is often performed inefficiently.

### SUMMARY

The present disclosure describes data storage systems configured to dynamically store data to data storage devices within pre-defined cooling zones. In some examples, a chassis is divided into different cooling zones that each include a number of data storage devices. In one example, a controller determines which cooling zone to store data in. For example, the controller may store data that is accessed (e.g., read and/or written) frequently in a “hot zone” near the front of the chassis closest to the cool-air inlet, and store data that is accessed relatively less frequently in a “cold zone” in the back of the chassis near the fans. Accessing data frequently may increase the operating temperature of the data storage device that stores the data relative to data storage devices that store data that is accessed infrequently. Thus, storing data that is accessed frequently on data storage devices in the “hot zone” relatively closes to the cool-air inlet and data that is accessed relatively infrequently on data storage devices further away from the cool-air inlet may enable the system to cool the data storage devices more efficiently. In this way, the controller may more efficiently cool data storage devices while potentially increasing performance and reliability of the data storage devices.

In one example, a method includes receiving, by a controller and from a host device, a write command including data to be stored and a logical block address for the data. The method also includes selecting, by the controller and from a pre-defined plurality of cooling zones of a data storage chassis, each cooling zone of the plurality of cooling zones including one or more data storage devices, a cooling zone in which to store the data. The method further includes writing the data to a data storage device in the cooling zone.

In another example, a computing device includes at least one processor and memory. The memory includes instructions that, when executed by the at least one processor, cause the at least one processor to receive, from a host device, a write command including data to be stored and a logical block address for the data. The memory also includes instructions that, when executed, cause the at least one processor to select, from a pre-defined plurality of cooling zones of a data storage chassis, each cooling zone of the plurality of cooling zones including one or more data storage devices, a cooling zone in which to store the data. The memory also includes instructions that, when executed, cause the at least one processor to write the data to a data storage device in the cooling zone.

In yet another example, a computer-readable storage medium comprising instructions that, when executed, cause at least one processor of a computing device to receive, from a host device, a write command including data to be stored and a logical block address for the data. The instructions, when executed, also cause the at least one processor to select, from a pre-defined plurality of cooling zones of a data storage chassis, each cooling zone of the plurality of cooling zones including one or more data storage devices, a cooling zone in which to store the data. The instructions, when executed, also cause the at least one processor to write the data to a data storage device in the cooling zone.

These and other features and aspects of various examples may be understood in view of the following detailed discussion and accompanying drawings.

### BRIEF DESCRIPTION OF THE DRAWINGS

FIG. 1 is a block diagram of a data storage system configured to dynamically store data to data storage devices within pre-defined cooling zones, in accordance with one or more aspects of the present disclosure.

FIG. 2 is a block diagram illustrating an example controller configured to dynamically store data to data storage devices within pre-defined cooling zones, in accordance with one or more aspects of the present disclosure.

FIG. 3 is a flow diagram illustrating example operations of a data storage system configured to dynamically store data to data storage devices within pre-defined cooling zones, in accordance with one or more aspects of the present disclosure.

### DETAILED DESCRIPTION

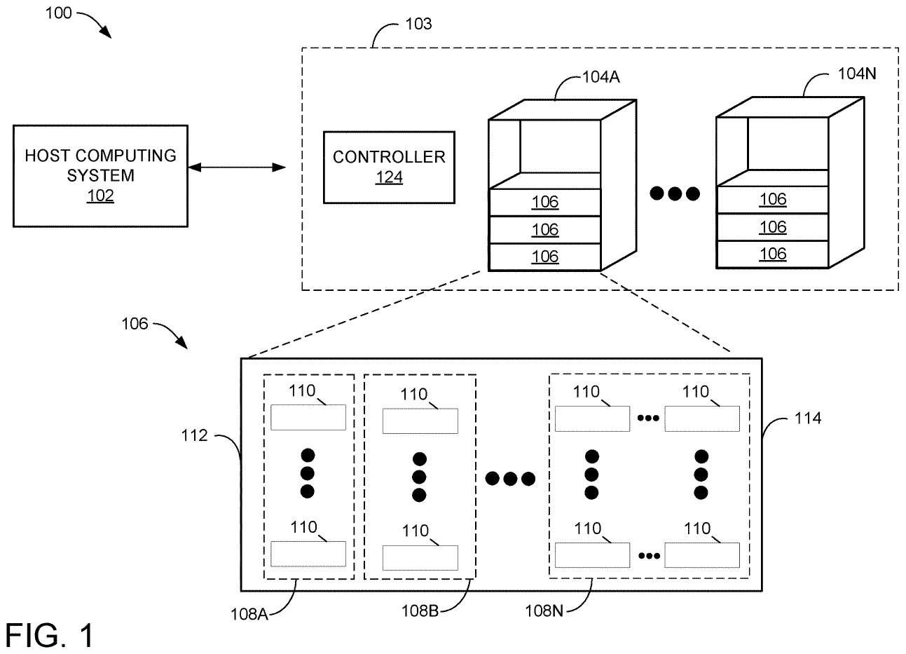

FIG. 1 is a block diagram of a data storage system configured to dynamically store data to data storage devices within pre-defined cooling zones, in accordance with one embodiment. Environment 100 includes a host computing system 102 and data storage system 103.

Host computing system 102 represents any type of computing system that is configured to read data from and write data to a data storage device. Examples of host computing system 102 include cloud computing environments, servers, desktop computers, laptop computers, mobile phones, tablet computers, televisions, automobiles, or any other type of mobile or non-mobile computing device that is configured to read and write data.

Data storage system 103 includes at least one data storage rack 104 and a controller 124. As illustrated in FIG. 1, data storage system 103 includes a plurality of data storage racks 104A-104N (collectively, data storage racks 104). Each data storage rack 104 includes a plurality of chassis 106. In some examples, each chassis 106 is removable from data storage rack 104. Each chassis 106 is configured to store a plurality of data storage devices 110. Examples of data storage devices 110 include hard disk drives (HDDs), solid state drives (SSDs), and magnetic tape drives, among others.

Each chassis 106 includes a plurality of pre-defined cooling zones 108A-108N (collectively, cooling zones 108). Each cooling zone of cooling zones 108 includes one or more data storage devices 110. Data storage devices 110 may be arranged as a series of rows, columns, or any other arrangement. While FIG. 1 illustrates cooling zones 108A and 108B as including a single column of data storage devices 110, each of cooling zones 108 may include any number of data storage devices 110 arranged in any number of rows and/or columns or any other arrangement.

In the example of FIG. 1, cooling zone 108A is located proximate a cool-air inlet 112 of chassis 106 (e.g., the front of chassis 106) and cooling zone 108N is located proximate a hot-air exhaust outlet 114 of chassis 106 (e.g., the rear of chassis 106). In some examples, chassis 106 includes one or more cooling zones (e.g., cooling zone 108B) located between cooling zone 108A and cooling zone 108N. In some scenarios, relatively cool air (e.g., air-conditioned air) flows into chassis 106 at cool-air inlet 112 to cool data storage devices 110. As the air flows from cool-air inlet 112 and over data storage devices 110 disposed within cooling zone 108A, the air absorbs heat from data storage devices 110, thus cooling data storage devices 110. The air warms up as the air travels from cooling zone 108A through cooling zone 108B, thus providing less cooling to data storage devices 110 within cooling zone 108B compared to the cooling provided to data storage devices 110 within cooling zone 108A. As the air moves towards the hot-air exhaust outlet 114 of chassis 106, the air continues to warm and provides less cooling to data storage devices 110 within cooling zones further back in chassis 106.

Controller 124 is configured to facilitate data transfers between host computing system 102 and data storage devices 110. Controller 124 may include hardware, hardware and software, hardware and firmware, or a combination thereof suitable to perform the techniques attributed to controller 124 herein. Examples of controller 124 include processors, microprocessors, peripheral interface controllers (“PICs”), digital signal processors (“DSPs”), application-specific integrated circuits (“ASICs”), systems on chips (“SoCs”), field programmable gate arrays (FPGAs), or the like, as well as any combination of such components. When controller 124 includes software or firmware, controller 124 further includes any necessary hardware for storing and executing the software or firmware, such as one or more processors or processing units (e.g., DSP, ASIC, FPGA, or any other integrated or discrete logic circuitry).

Controller 124 receives a command (e.g., a read command, a write command) that identifies a logical block address from host computing system 102. For example, the command may include a write command that includes data to be stored to one or more data storage devices 110 and at least one LBA associated with the data. In another example, the command includes a read command that identifies an LBA for data stored on one or more data storage devices 110.

In accordance with techniques of this disclosure, controller 124 is configured to dynamically select a cooling zone 108 in which to store the data. Controller 124 may select one of cooling zones 108 based on block access data associated with the LBA. In one example, the block access data may include data indicating how often the data associated with the LBA is accessed (e.g., read and/or written). For example, the block access data may include data indicating each time the LBA was accessed, when the LBA was most recently accessed, how often the LBA is accessed over time, or a combination thereof.

In some scenarios, controller 124 may determine whether the block access data associated with an LBA satisfies a data access threshold associated with one of cooling zones 108 (e.g., cooling zone 108A). For example, controller 124 may determine that the block access data satisfies the data access threshold associated with cooling zone 108A in response to determining the LBA was most recently accessed within a threshold amount of time. In another example, controller 124 may determine that the block access data satisfies the data access threshold associated with cooling zone 108A in response to determining the LBA was accessed at least a threshold amount (e.g., within a certain amount of time, such as at least 100 reads and/or writes within the last 30 days).

Responsive to determining that the block access data associated with the LBA satisfies the data access threshold associated with cooling zone 108A, controller 124 selects cooling zone 108A for storing the data associated with the LBA. For example, controller 124 may store the data associated with the LBA within cooling zone 108A by outputting a write command to one of data storage devices 110 located within cooling zone 108A. Responsive to determining the block access data associated with the LBA does not satisfy the data access threshold associated with cooling zone 108A, controller 124 may select another cooling zone of cooling zones 108 for storing the data.

In some examples, controller 124 compares the block access data associated with the LBA to two or more different data access thresholds that are each associated with a respective cooling zone of cooling zones 108. For example, cooling zone 108A may be associated with one data access threshold and cooling zone 108B may be associated with a different data access threshold. In one example, controller 124 determines whether the block access data associated with the LBAs satisfies a data access threshold for cooling zone 108B in response to determining that the block access data associated with the LBA does not satisfy the data access threshold for cooling zone 108A. In one example, controller 124 selects cooling zone 108B in response to determining that the block access data associated with the LBA satisfies the data access threshold for cooling zone 108B (e.g., at least 10 reads and/or writes within the last 30 days) but does not satisfy the data access threshold for cooling zone 108A. In another example, controller 124 may determine whether the block access data associated with the LBA satisfies a data access threshold for cooling zone 108A in response to determining that the block access data associated with the LBA satisfies the data access threshold for cooling zone 108B.

According some instances, controller 124 selects another cooling zone of cooling zones 108 (e.g., cooling zone 108N) in response to determining that the block access data associated with the LBA does not satisfy the data access threshold for the other cooling zones. For instance, controller 124 may select cooling zone 108N in response to determining that the block access data associated with the LBA does not satisfy the data access thresholds for cooling zones 108A and 108B.

Responsive to selecting a cooling zone, controller 124 writes the data to one or more storage devices 110 located in the selected cooling zone. For example, controller 124 may select a particular data storage device 110 located within the selected cooling zone and output the write command to the particular data storage device. In one example, controller 124 selects a particular data storage device 110 based on the input/output operations per second (IOPS) of the data storage devices 110 in the selected cooling zone. For example, controller 124 may select the data storage device 110 with the lowest IOPS among the devices 110 in the selected cooling zone (e.g., to balance the IOPS across all of the devices 110 within the selected cooling zone).

In this way, techniques of this disclosure may enable a controller to dynamically store data to data storage devices within different cooling zones. For example, the controller store data that is accessed relatively frequently (e.g., compared to other data) to data storage devices located in a cooling zone that is proximate to a cool-air inlet and store data that is accessed relatively infrequently to data storage devices located in other cooling zones. In contrast to some examples that attempt to spread a workload evenly across data storage devices within a chassis, rack, or storage environment, the controller may store data that is accessed more frequently in data storage devices closest to fresh, cool, air-conditioned air. Storing data that is accessed more frequently to data storage devices within a given region of a chassis may increase the operating temperature of the data storage devices within that region while potentially decreasing the operating temperature of data storage devices within other regions of the chassis. Increasing the operating temperature of data storage devices located in a cooling region that is proximate to the cool-air inlet of the chassis may enable the data storage devices with higher operating temperatures to cool down more efficiently, which may increase the longevity of the data storage devices within the chassis, rack, or the entire storage environment.

While controller 124 is described as selected pre-defined cooling zones 108 within a single chassis 106, in some instances, controller 124 may select cooling zones 108 across multiple chassis 106 within a single rack 104 or across racks 104 within storage environment 103. For instance, controller 124 may store data associated with one LBA in cooling zone 108A on one chassis 106 and may store data associated with another LBA in cooling zone 108A on a different chassis 106. By dynamically selecting cooling zones across different chassis and racks, the controller 124 may enable system 103 to more efficiently cool data storage devices across the entire storage environment, which may increase the reliability and/or lifespan of the data storage devices.

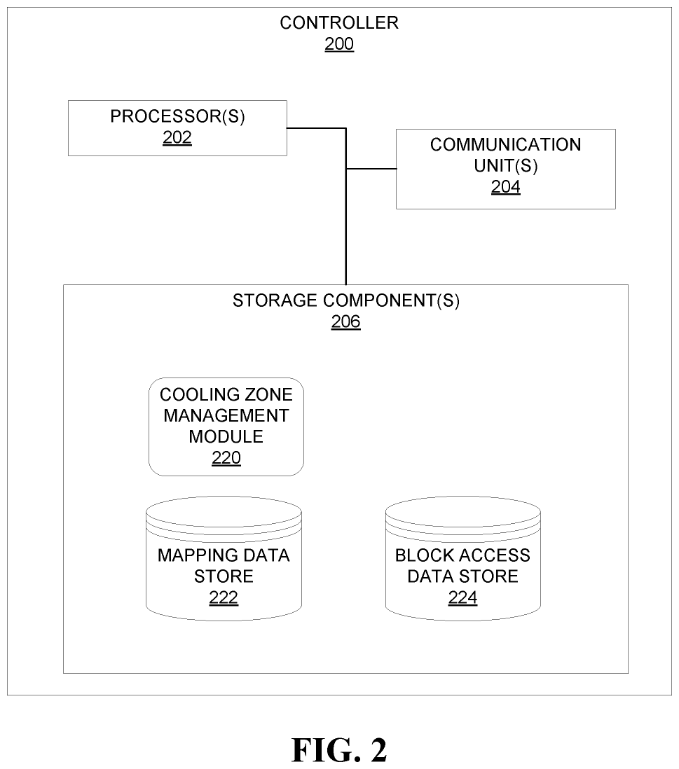

FIG. 2 is a block diagram illustrating an example controller configured to dynamically store data to data storage devices within pre-defined cooling zones, in accordance with one or more aspects of the present disclosure. Controller 200 is an example of controller 124 of FIG. 1. Many other examples of controller 200 may be used in other instances and may include a subset of components included in controller 200 or may include additional components not shown in FIG. 2. FIG. 2 is described in the context of environment 100 of FIG. 1.

As shown in the example of FIG. 2, controller 200 includes one or more processors 202, one or more communication units 204, and one or more storage components 206. Storage components 206 may include cooling zone management module (CZMM) 220, mapping data store 222, and block access data store 224.

One or more communication units 204 may communicate with external devices (e.g., host computing system 102 of FIG. 1) via one or more wired and/or wireless networks by transmitting and/or receiving network signals on the one or more networks. Examples of communication units 204 include a network interface card (e.g., an ethernet card), an optical transceiver, a radio frequency transceiver, or any other type of device configured to send and receive information.

One or more processors 202 may implement functionality and/or execute instructions associated with controller 200. Examples of processors include microprocessors, peripheral interface controllers (“PICs”), application-specific integrated circuits (“ASICs”), systems on chips (“SoCs”), field programmable gate arrays (FPGAs), etc. Cooling zone management module 220 may be operable by processors 202 to perform various actions, operations, or functions of controller 200. For examples, processors 202 may retrieve and execute instructions stored by storage components 206 that cause processors 202 to perform the operations of cooling zone management module 220. The instructions, when executed by processors 202, may cause controller 200 to store data within storage components 206.

One or more storage components 206 may store data or information for processing during operation of controller 200 (e.g., controller 200 may store data accessed by cooling zone management module 220 during execution at controller 200). In some examples, storage components 206 include tangible memory configured to store data, such as volatile or non-volatile memory (e.g., flash memory, solid state devices (SSDs), hard disk drives (HDDs), random access memory (RAM), read only memory (ROM), among others). It should be understood, however, that memory does not include connections, carrier waves, signals, or other transient signal transport mechanism, but are instead directed to non-transient, tangible memory. In some examples, the memory may be external to processors 202 (e.g., may be external to a package in which one or more processors are housed). The memory may store computer-executable instructions which may be executed by processors 202 to perform the functionality of cooling zone management module 220.

In some examples, cooling zone management module (CZMM) 220 receives a command (e.g., a read command, a write command) from host computing system 102. In one example, the command includes a write command that includes data to be stored to one or more data storage devices 110 and at least one logical block address (LBA) associated with the data.

CZMM 220 dynamically selects one of cooling zones 108 based on block access data store 224. Block access data store 224 may include data identifying each LBA stored within data storage devices 110 and block access data associated with each respective LBA. In one example, the block access data indicates how often each respective LBA is accessed (e.g., read and/or written). For example, the block access data may include data indicating each time a respective LBA was accessed, when each LBA was most recently accessed, how often each LBA is accessed over time, or a combination thereof. In some examples, block access data store 224 includes block access data by command type (e.g., read command or write command). For example, block access data store 224 may include read access data indicating how often each LBA is read and write access data indicating how often each LBA is written.

In some scenarios, CZMM 220 may determine whether the block access data associated with a particular LBA satisfies a data access threshold. The data access threshold may include a date, an amount of time, an amount of usage, or other threshold data. For example, CZMM 220 may determine that the block access data satisfies the data access threshold in response to determining that the LBA was most recently accessed prior to a threshold date or in response to determining that the LBA was accessed more than a threshold amount (e.g., within a certain amount of time). In one example, CZMM 220 determines that the block access data does not satisfy the data access threshold in response to determining that the LBA is accessed less than a threshold amount or has not been accessed within a threshold amount of time.

CZMM 220 may dynamically determine the data access threshold. In one instance, CZMM 220 determines the data access threshold based on the block access data associated with a plurality of LBAs. For instance, CZMM 220 may query the block access data and determine data usage for a subset of the LBAs (e.g., the most used LBAs, such as the top 10% of LBAs). In such instances, CZMM 220 may set the data access threshold to be greater than or equal to the data usage for the subset of LBAs.

CZMM 220 dynamically assigns a cooling zone to the LBA in response to determining whether the block access data associated with the LBA satisfies the data access threshold. For example, the block access data associated with the LBA may indicate that the LBA is accessed infrequently (e.g., the data associated with the LBA is “cold” data). In such examples, CZMM 220 may determine that the block access data associated with the LBA does not satisfy (e.g., is less than) the data access threshold. In response to determining that the that the block access data associated with the LBA does not satisfy the data access threshold, CZMM 220 may assign the LBA to a cooling zone 108N proximate to the exhaust outlet 114 of chassis 106.

In another example, the block access data associated with the LBA may indicate that the LBA is accessed frequently (e.g., the data associated with the LBA is “hot” data). In such examples, CZMM 220 may determine that the block access data associated with the LBA satisfies (e.g., is greater than or equal to) the data access threshold. In response to determining that the that the block access data associated with the LBA satisfies the data access threshold, CZMM 220 may assign the LBA to a cooling zone 108A proximate to the cool-air inlet 112 of chassis 106.

In some instances, CZMM 220 determines whether the block access data associated with the LBA satisfies two different data access thresholds that are each associated with a respective cooling zone. For instance, the block access data associated with the LBA may indicate that the LBA is accessed moderately frequently (e.g., the data associated with the LBA is “warm” data). In such instances, CZMM 220 may determine that the block access data associated with the LBA satisfies (e.g., is greater than or equal to) one data access threshold associated with one cooling zone (e.g., cooling zone 108B) and does not satisfy (e.g., is less than) another data access threshold associated with a different cooling zone (e.g., cooling zone 108A). In response to determining that the that the block access data satisfies one data access threshold and does not satisfy another data access threshold, CZMM 220 may assign the LBA to the cooling zone associated with the satisfied data access threshold (e.g., cooling zone 108B proximate a middle region of chassis 106). That is, in one example, CZMM 220 assigns the LBA to cooling zone 108B that is between the cooling zone 108A proximate to cool-air inlet 112 and cooling zone 108N proximate to the exhaust outlet 114.

In some examples, each cooling zone may be associated with different data access threshold for different types of data access. For example, each cooling zone 108 may be associated with a read threshold and a write threshold that is different from the read threshold. In one example, data storage devices 110 may include energy assisted magnetic recording devices(e.g., heat-assisted magnetic recording (HAMR) or microwave assisted magnetic recording (MAMR) devices) and may have relatively high operating temperatures during write operations compared to the operating temperatures during read operations. CZMM 220 may determine whether the block access data associated with the logical block address satisfies the data access threshold by determining whether the write access data satisfies a write threshold and/or determining whether the read access data satisfies a different read threshold. In one example, the write threshold may be lower than the read threshold. In this way, data that is written more frequently may be assigned to a cooling zone closer to cool-air inlet 112 while data that is read more frequently may be assigned to cooling zones further from the cool-air inlet 112.

Responsive to selecting a cooling zone (e.g., cooling zone 108B), CZMM 220 writes the data to one or more storage devices 110 located in the selected cooling zone. For example, CZMM 220 may identify a particular data storage device 110 located within the selected cooling zone 108B and output the write command to the particular data storage device 110.

CZMM 220 may update mapping data store 222 after selecting the particular data storage device 110 to store the data. For example, mapping data store 222 may include data mapping LBAs to respective physical block addresses (PBAs). In one example, CZMM 220 may map the LBA to a PBA of the selected data storage device 110.

CZMM 220 may move data from one cooling zone to another cooling zone. For example, an LBA that was previously accessed frequently may not be accessed as frequently later (or vice versa). CZMM 220 may re-determine whether the block access data associated with the LBA satisfies one or more data access thresholds. In one example, CZMM 220 assigns the LBA to a different cooling zone in response to determining that the block access data associated with the LBA no longer satisfies the data access threshold associated with the current cooling zone (e.g., cooling zone 108B) for the LBA (e.g., the LBA is now accessed less frequently, such that the data associated with that LBA is “cold”). In another example, CZMM 220 assigns the LBA to a different cooling zone in response to determining that the block access data associated with the LBA now satisfies the data access threshold associated with a different cooling zone (e.g., the LBA is now accessed more frequently, such that the data associated with that LBA is “hot”). Responsive to assigning the LBA to a different cooling zone, CZMM 220 writes the data to a data storage device 110 located in the different cooling zone and updates mapping data store 222.

In some examples, CZMM 220 moves data that is associated with one LBA and that is stored in a particular cooling zone to a different cooling zone in response to determining that data associated with a different LBA should be stored in the particular cooling zone. For example, CZMM 220 may determine that data associated with a particular LBA should be stored in cooling zone 108B (e.g., moved from a different cooling zone or written for a first time) and that at least a threshold amount of cooling zone 108B already stores data. In some examples, CZMM 220 may select an LBA associated with data that is currently stored in cooling zone 108B and move that data to a different cooling zone (e.g., cooling zone 108N) to make room for the data associated with the particular LBA to be stored in cooling zone 108B.

In one example, the data access threshold associated CZMM 220 may be predetermined. In some examples, CZMM 220 adjusts the data access threshold associated with the cooling zone (e.g., 108B) in response to associating another LBA with the cooling zone. For example, responsive to associating another LBA with cooling zone 108B, CZMM 220 may adjust the data access threshold associated with cooling zone 108B based on a subset of LBAs associated with cooling zone 108B. CZMM 220 may adjust the data access threshold based on the most frequently accessed LBAs or the most recently accessed LBAs.

In one example, CZMM 220 moves data currently stored in cooling zone 108B in response to adjusting the data access threshold associated with cooling zone 108B. For example, CZMM 220 may determine that the data associated with the one LBA does not satisfy (e.g., is less than) the adjusted data access threshold associated with cooling zone 108B. In response, CZMM 220 may associate the LBA with another cooling zone (e.g., 108N), write the data associated with the LBA to another cooling zone 108 (e.g., a cooling zone closer to the exhaust outlet 114), and update mapping data store 222.

In this way, CZMM 220 may dynamically adjust where data is stored by moving data that is accessed more to data storage devices located in regions of chassis 106 that are closer to the cool-air inlet. Storing data that is accessed more in data storage devices closer to the cool-air inlet may reduce the amount of heat generated by data storage devices further from the cool-air inlet and increase the heat generated by data storage devices closer to the cool-air inlet. In this way, CZMM 220 may cause the data storage devices that perform the highest workloads and have the highest temperatures to be located in the cool-air inlet where those data storage devices will receive the coolest air. Thus, CZMM 220 may increase the life-expectancy of data storage devices by more effectively cooling data storage devices that have the highest operating temperatures.

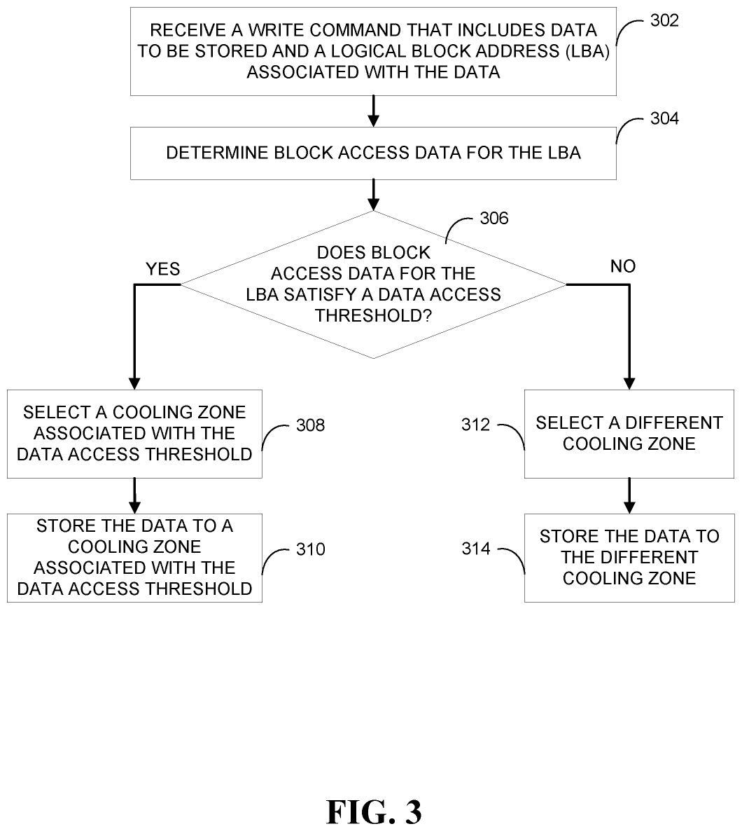

FIG. 3 is a flow diagram illustrating example operations of a data storage system configured to dynamically store data to data storage devices within pre-defined cooling zones, in accordance with one or more aspects of the present disclosure. The process of FIG. 3 may be performed by one or more processors of a controller, such as controller 124 as illustrated in FIG. 1. For purposes of illustration only, FIG. 3 is described below within the context of environment 100 of FIG. 1.

Controller 124 receives a write command that includes data to be stored and at least one LBA associated with the data (302). For example, controller 124 may receive the data associated with the LBA for a first time or may receive updated data associated with the LBA (e.g., if controller 124 previously received data associated with the same LBA).

Controller 124 selects one of cooling zones 108 based on block access data associated with the LBA. The block access data may include data indicating how often the data associated with the LBA is accessed (e.g., by host computing system 102), such as data indicating each time the LBA was accessed, when the LBA was most recently accessed, and/or how often the LBA is accessed over time.

In one example, controller 124 determines whether the block access data associated with an LBA satisfies (e.g., is greater than or equal to) a data access threshold associated with one of cooling zones 108 (304). The data access threshold may include a threshold date, amount of time, amount of usage, or the like. In one example, controller 124 determines that the block access data associated with the LBA satisfies the data access threshold associated with a particular cooling zone in response to determining that the LBA was accessed at least a threshold amount (e.g., within a predefined amount of time, such as the last 30 days).

Responsive to determining that the block access data associated with the LBA satisfies the data access threshold associated with a particular cooling zone, such as cooling zone 108A, (“YES” path of 304), controller 124 selects the particular cooling zone for storing the data associated with the LBA (306). In one example, controller 124 selects a data storage device 110 within the selected cooling zone 108A. Responsive to selecting the data storage device 110, controller 124 stores the data associated with the LBA within the cooling zone 108A by outputting a write command to the selected data storage device 110 located within cooling zone 108A (308).

In one example, controller 124 determines that the block access data associated with the LBA does not satisfy the data access threshold associated with a particular cooling zone in response to determining that the LBA was not accessed within a threshold amount of time (e.g., within the last 6 months). Responsive to determining the block access data associated with the LBA does not satisfy the data access threshold associated with the particular cooling zone 108 (“NO” path of 304), controller 124 may select another cooling zone of cooling zones 108 for storing the data (310). For example, controller 124 may select cooling zone 108B. Responsive to selecting cooling zone 108B, controller 124 selects a data storage device 110 within cooling zone 108B and stores the data associated with the LBA to the data storage device by outputting a write command to the selected data storage device 110 located within cooling zone 108B (312).

In some examples, controller 124 may re-determine whether the block access data associated with the LBA satisfies the data access threshold associated with the cooling zone in which the data is stored. For example, controller 124 may periodically or occasionally query block access data store 224 and determine whether the block access data satisfies the data access threshold.

In one example, controller 124 determines whether the block access data associated with the LBA satisfies a data access threshold associated with a different cooling zone 108. For example, controller 124 may determine whether the block access data satisfies a data access threshold associated with a cooling zone closer to the cool-air inlet 112 of chassis 106 and/or a data access threshold associated with a cooling zone closer to exhaust outlet 114 of chassis 106. In some examples, controller 124 moves the data associated with the LBA to a cooling zone closer to the cool-air inlet 112 in response to determining the updated block access data associated with the LBA satisfies the data access threshold associated with a cooling zone 108 closer to the cool-air inlet 112 (relative to the cooling zone in which the data is currently stored).

Controller 124 may move the data associated with the LBA to a cooling zone closer to the exhaust outlet 114 in response to determining the updated block access data associated with the LBA satisfies the data access threshold associated with a cooling zone 108 closer to the exhaust outlet 114 (relative to the cooling zone in which the data is currently stored). For example, controller 124 may determine that the updated block access data associated with the LBA no longer satisfies the data access threshold associated with cooling zone 108B but does satisfy the data access threshold associated with cooling zone 108N.

In some scenarios, controller 124 adjusts the data access threshold associated with one or more cooling zones 108. Controller 124 may move data from one cooling zone 108 to another cooling zone 108 in response to determining whether the block access data associated with the LBA satisfies one or more adjusted the data access threshold. For example, controller 124 may move the data from one cooling zone (e.g., 108B) to a cooling zone closer to cool-air intake 112 (e.g., 108A) in response to determining that the block access data satisfies the adjusted data access threshold for cooling zone 108A. In another example, controller 124 may move data from cooling zone 108B to another cooling zone closer to the exhaust outlet 114 in response to determining the block access data does not satisfy the adjusted data access threshold for cooling zone 108B.

Various examples have been described. These and other examples are within the scope of the following claims.

1. A method comprising:
receiving, by a controller and from a host device, a first write command including first data to be stored and a first logical block address associated with the first data and a second write command including second data to be stored and a second logical block address associated with the second data;
selecting, by the controller and from a pre-defined plurality of cooling zones of a data storage chassis, each cooling zone of the plurality of cooling zones including one or more data storage devices, a first cooling zone in which to store the first data based on first block access data associated with the first logical block address and a write threshold;
writing the first data to a first data storage device in the first cooling zone;
selecting, by the controller, a second cooling zone in which to store the second data based on second block access data associated with the second logical block address and a read threshold, wherein the second cooling zone is different than the first cooling zone and the write threshold is less than the read threshold; and
writing the second data to a second data storage device in the second cooling zone.

2. (canceled).

3. The method of claim 1, wherein the first block access data includes data indicating how often the first data is written and the second block access data includes data indicating how often the second data is read.

4. The method of claim 1, wherein the read threshold is a first read threshold, the method further comprising:
after writing the second data to the second data storage device in the second cooling zone, determining that the second block access data associated with the second logical block address satisfies a second read threshold associated with the first cooling zone; and
writing the second data to the first cooling zone in response to determining that the block access data associated with the second logical block address satisfies the second read threshold.

5. The method of claim 1, wherein the first cooling zone is located closer to an air inlet of the chassis relative to the second cooling zone.

6. The method of claim 1, the method further comprising:
after writing the first data to the first data storage device in the first cooling zone, determining that the block access data associated with the first logical block address does not satisfy the write threshold; and
writing the first data to the second cooling zone in response to determining that the block access data associated with the first logical block address does not satisfy the write threshold, wherein the second cooling zone is located closer to an exhaust outlet of the chassis relative to the first cooling zone.

7. The method of claim,
wherein the block access data associated with the first logical block address includes write access data indicating how often the first logical block address is written and the block access data associated with the second logical block address includes read data indicating how often the second logical block address is read.

8. The method of claim 1, further comprising:
determining the write threshold based on block access data associated with a plurality of logical block addresses.

9. A computing device comprising:
at least one processor; and
memory comprising instructions that, when executed by the at least one processor, cause the at least one processor to:
receive, from a host device, a first write command including first data to be stored and a first logical block address associated with the first data and a second write command including second data to be stored and a second logical block address associated with the second data;
select, from a pre-defined plurality of cooling zones of a data storage chassis, each cooling zone of the plurality of cooling zones including one or more data storage devices, a first cooling zone in which to store the first data based on first block access data associated with the first logical block address and a write threshold; write the data to a data storage device in the cooling zone;
selecting, by the controller, a second cooling zone in which to store the second data based on second block access data associated with the second logical block address and a read threshold, wherein the second cooling zone is different than the first cooling zone and the write threshold is less than the read threshold; and
writing the second data to a second data storage device in the second cooling zone.

10. (canceled).

11. The computing device of claim 9, wherein the block access data includes data indicating how often the first data is written and the second block access data includes data indicating how often the second data is read.

12. The computing device of claim 9, wherein the read threshold is a first read, and wherein execution of the instructions further causes the at least one processor to:
after writing the second data to the second data storage device in the second cooling zone, determine that the second block access data associated with the second logical block address satisfies a second read threshold associated with the first cooling zone; and
write the second data to the first cooling zone in response to determining that the block access data associated with the second logical block address satisfies the second read threshold.

13. The computing device of claim 9, wherein the first cooling zone is located closer to an air inlet of the chassis relative to the second cooling zone.

14. The computing device of claim 9, threshold, and wherein execution of the instructions further causes the at least one processor to:
after writing the first data to the first data storage device in the first cooling zone, determine that the block access data associated with the first logical block address does not satisfy the write threshold; and
write the first data to the second cooling zone in response to determining that the block access data associated with the first logical block address does not satisfy the write threshold, wherein the second cooling zone is located closer to an exhaust outlet of the chassis relative to the first cooling zone.

15. The computing device of claim 9, wherein the block access data associated with the first logical block address includes write data indicating how often the first logical block address is written and the block access data associated with the second logical block address includes read data indicating how often the second logical block address is read.

16. The computing device of claim 9, wherein execution of the instructions further causes the at least one processor to:
determine the write threshold based on block access data associated with a plurality of logical block addresses.

17. A non-transitory computer-readable storage medium comprising instructions that, when executed, cause at least one processor of a computing device to:
receive, from a host device, a first write command including first data to be stored and a first logical block address associated with the first data and a second write command including second data to be stored and a second logical block address associated with the second data;
select, from a pre-defined plurality of cooling zones of a data storage chassis, each cooling zone of the plurality of cooling zones including one or more data storage devices, a first cooling zone in which to store the first data based on first block access data associated with the first logical block address and a write threshold;
write the first data to a first data storage device in the first cooling zone;
select a second cooling zone in which to store the second data based on second block access data associated with the second logical block address and a read threshold, wherein the second cooling zone is different than the first cooling zone and the write threshold is less than the read threshold; and
write the second data to a second data storage device in the second cooling zone.

18. (canceled).

19. The non-transitory computer-readable storage medium of claim 17, wherein the read threshold is a first read threshold, and wherein execution of the instructions further causes the at least one processor to:
after writing the second data to the second first data storage device in the second cooling zone, determine that the second block access data associated with the second logical block address satisfies a second read threshold associated with the first cooling zone;
and write the second data to the first cooling zone in response to determining that the block access data associated with the second logical block address satisfies the second read threshold, wherein the second cooling zone is located closer to an air inlet of the chassis relative to the first cooling zone.

20. The non-transitory computer-readable storage medium of claim 17, wherein execution of the instructions further causes the at least one processor to:
responsive to determining that the first block access data associated with the first logical block address does not satisfy the write threshold,
write the first data to another data storage device located in the second cooling zone.
